(19) United States
(12) Patent Application Publication
(10) Pub. No.: US 2022/0007551 A1
(43) Pub. Date: Jan. 6, 2022

(54) IMPINGING JET COLDPLATE FOR POWER ELECTRONICS WITH ENHANCED HEAT TRANSFER

(71) Applicants: Vimaldoss JESUDHAS, Windsor (CA); Ram BALACHANDAR, Windsor (CA); Ron BARRON, Windsor (CA); Narayan KAR, Windsor (CA); Martin WINTER, Dietach (AT); Gerd SCHLAGER, Kefermarkt (AT); Lakshmi Varaha IYER, Troy, MI (US); MAGNA INTERNATIONAL INC., Aurora (CA)

(72) Inventors: Vimaldoss JESUDHAS, Windsor (CA); Ram BALACHANDAR, Windsor (CA); Ron BARRON, Windsor (CA); Narayan KAR, Windsor (CA); Martin WINTER, Dietach (AT); Gerd SCHLAGER, Kefermarkt (AT); Lakshmi Varaha IYER, Troy, MI (US)

(21) Appl. No.: 17/293,494

(22) PCT Filed: Nov. 13, 2019
(86) PCT No.: PCT/US2019/061208

§ 371 Date: May 13, 2021

Related U.S. Application Data
(60) Provisional application No. 62/760,322, filed on Nov. 13, 2018.

(51) Int. Cl. H05K 7/20; H05K 1/02

(52) U.S. Cl. CPC H05K 7/20927; B33Y 80/00; H05K 1/0203; H05K 7/20509

(57) ABSTRACT

A coldplate for removing heat from one or more heat sources, such as power electronics devices, includes a baseplate including a first surface in thermally-conductive communication with the heat sources. The baseplate includes a second surface opposite the first surface to transfer heat into a cooling fluid in contact therewith. The second surface includes a peripheral flange surrounding a central region having a plurality of parallel ribs, which increase the surface area to improve heat transfer from the baseplate and into the fluid. A housing abuts the peripheral flange of the baseplate to define a cooling passage for circulation of the cooling fluid. A jet-array plate subdivides the cooling passage into a supply header and a main channel and defines a plurality of orifices to convey the fluid into the main channel and to direct the fluid toward predetermined zones on the baseplate.

### CROSS-REFERENCE TO RELATED APPLICATIONS

This PCT International Patent application claims the benefit of and priority to U.S. Provisional Patent Application Ser. No. 62/760,322 filed on Nov. 13, 2018, titled “Impinging Jet Coldplate for Power Electronics with Enhanced Heat Transfer,” the entire disclosure of which is hereby incorporated by reference.

### FIELD

The present disclosure relates generally to a coldplate for cooling power electronics devices. More specifically, it relates to a coldplate for cooling power electronics devices in an automotive application.

### BACKGROUND

Heat sources such as power electronics devices may generate a relatively large amount of heat that must be dissipated to prevent the devices from overheating and malfunctioning or being damaged. Heat dissipation may be accomplished using a variety of different cooling devices, including passive devices such as heat sinks and active devices that may transfer heat away from the heat source using a moving fluid. Various design considerations affect the type of cooling device or devices that may be employed. Some primary design considerations include cost, packaging constraints, and environmental conditions. One particularly harsh environment is in vehicular applications where interior temperatures can range from −40 to 170 degrees Fahrenheit.

### SUMMARY

A coldplate is provided for removing heat from a plurality of heat sources. The coldplate includes a baseplate of thermally-conductive material including a first surface in thermally-conductive communication with the heat sources. The coldplate also includes a second surface opposite the first surface, with the second surface being configured to transfer heat from the heat sources into a cooling fluid in contact therewith. A housing and the baseplate together define a cooling passage for circulation of the cooling fluid to remove heat from the baseplate. A jet-array plate is disposed in the cooling passage and extends parallel to and spaced apart from the baseplate to subdivide the cooling passage into a supply header opposite the baseplate and a main channel that extends between the jet-array plate and the baseplate. The jet-array plate defines a plurality of orifices extending therethrough to convey fluid from the supply header and into the main channel. The orifices are configured to direct the fluid toward predetermined zones on the second surface of the baseplate.

The coldplate of the present disclosure may be compact, light-weight and may offer maximum cooling performance within a small area.

### BRIEF DESCRIPTION OF THE DRAWINGS

Further details, features and advantages of designs of the invention result from the following description of embodiment examples in reference to the associated drawings.

FIG. 1 is a cut-away side view of an example coldplate of the present disclosure;

FIG. 2 is a perspective view of a baseplate for a coldplate;

FIG. 3 is a perspective view of a jet-array plate with chamfered orifices;

FIG. 4 is a cut-away side view of a coldplate including the jet-array plate of FIG. 3;

FIG. 5 is a transparent perspective view of an example coldplate according to embodiments of the present disclosure;

FIG. 6 is a schematic view of fluid passages within the example coldplate of FIG. 5;

FIG. 7 is a side view of the example coldplate of FIG. 5;

FIG. 8 is a schematic view of fluid passages within the example coldplate shown in FIG. 7; and

FIG. 9 is a cut-away side view of an example coldplate of the present disclosure.

### DETAILED DESCRIPTION

Recurring features are marked with identical reference numerals in the figures, in which an example embodiment of a coldplate 20, 120 for removing heat from one or more heat sources 10, 110, such as power electronic devices, on a circuit board 12 is disclosed. Such a coldplate 20, 120 is especially useful in automotive applications where thermal management is critical and where operation over a wide range of temperatures and conditions is required. The subject coldplate 20, 120 may be used, for example, to cool the heat sources 10, 110 in an electronic controller for an engine, transmission, audio/video, HVAC device, and/or another vehicular component. The subject coldplate 20, 120 may be especially well suited for new generation power converters that employ Gallium Nitride and/or Silicon Carbide switches, which have a relatively small form factor and which may have precisely known positions where generated heat is concentrated.

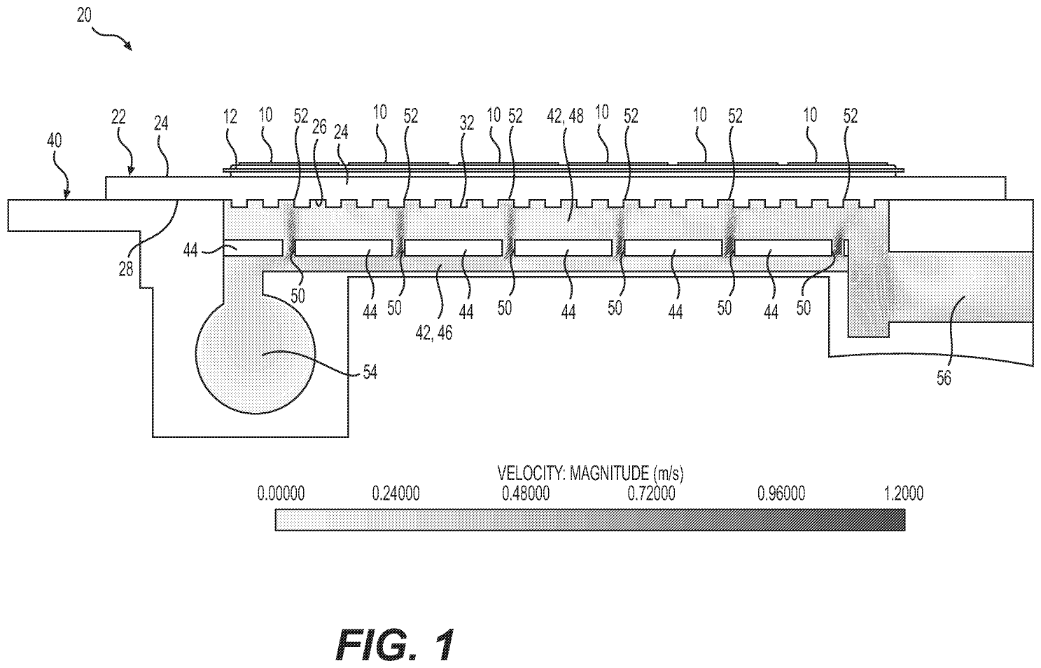

As shown in FIG. 1, the coldplate 20, 120 may be configured as a single-layer coldplate 20 including a first baseplate 22 of thermally-conductive material, such as metal, includes a first surface 24 in thermally-conductive communication with first heat sources 10. The first heat sources 10 may be in direct physical contact with the first baseplate 22 as shown in FIG. 1. Alternatively, a thermally-conductive device and/or substance may extend therebetween. For example, thermally-conductive paste may be used to enhance thermal conduction between the first heat sources 10 and the first baseplate 22. Other devices, such as a heat pipe, may transfer heat between the first heat sources 10 and the first baseplate 22, allowing the first heat sources 10 to be physically spaced apart from the first baseplate 22. The first heat sources 10 may be semiconductor switches, such as Si, SiC, and/or GaN-based devices. The first heat sources 10 may also be other devices such as, for example, capacitors, inductors, and/or transformers. The first baseplate 22 includes a second surface 26 opposite the first surface 24 and configured to transfer heat from the first heat sources 10 through the first baseplate 22 and into a fluid in contact with the second surface 26. In other words, the first baseplate 22 is preferably formed as a relatively thin sheet that is thick enough to maintain structural rigidity, but thin enough to efficiently conduct heat directly therethrough between the first surface 24 and the second surface 26.

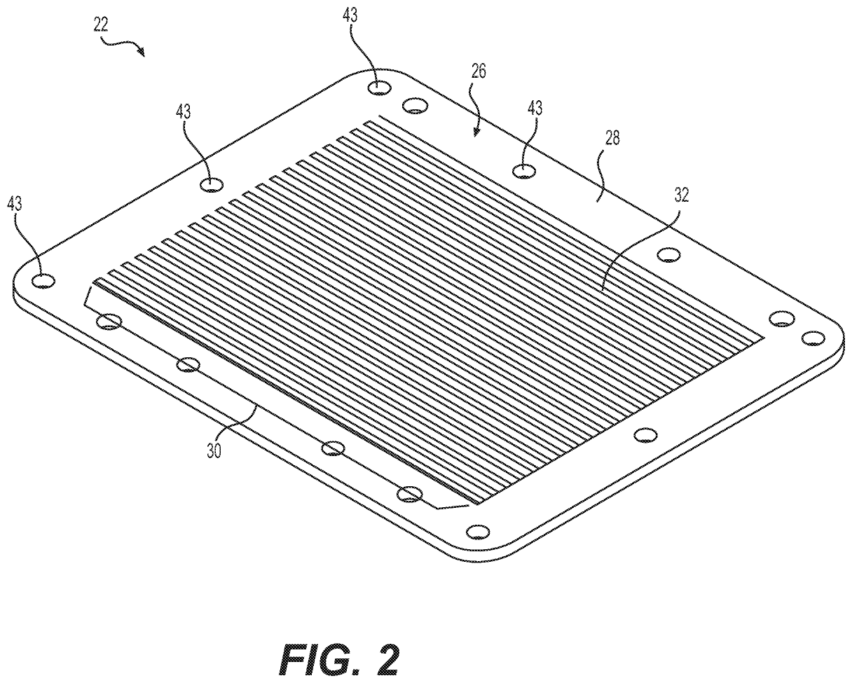

As shown in FIG. 2, the second surface 26 of the first baseplate 22 extends in a generally flat plane that includes a peripheral flange 28 that is generally flat and which surrounds a central region 30. The central region 30 of the first baseplate 22 defines a plurality of fins 32 extending transverse to the generally flat plane of the first baseplate 22 and into the cooling passage 42 to increase the surface area of the second surface 26 to improve heat transfer from the first baseplate 22 and into the fluid. In one embodiment, and as illustrated in the cross-section shown in FIG. 1, the fins 32 have a generally rectangular cross-section.

In the example embodiment shown in FIG. 2, the fins 32 are formed as a plurality of ribs 32, which extend parallel to one another. However, the fins 32 may be formed in other shapes or configurations, including posts, a staggered block configuration, and/or as a pattern formed in or on the lower surface of the first baseplate 22. The fins 32 may extend generally parallel to a primary direction of fluid flow through the coldplate 20. Alternatively, the fins 32 may extend generally perpendicularly to the primary direction of fluid flow through the coldplate 20. Alternatively, the fins 32 may extend at an oblique angle to the primary direction of fluid flow through the coldplate 20.

The fins 32 may be formed in the first baseplate 22 by any suitable process. For example, the fins 32 may be machined into the first baseplate 22. Alternatively or additionally, the fins 32 may be formed together with the first baseplate 22, for example, by casting. Alternatively or additionally, the fins 32 may be formed in the first baseplate 22 by compressive force, such as by stamping or rolling. Alternatively or additionally, the fins 32 may be formed in the first baseplate 22 by a 3D printing process, such as additive manufacturing (AM).

As shown in FIG. 1 the coldplate 20 also includes a housing 40 that abuts the peripheral flange 28 of the first baseplate 22, with the housing 40 and the first baseplate 22 together defining a cooling passage 42 for circulation of a cooling fluid to remove heat from the central region 30 of the first baseplate 22. The housing 40 may be made of a variety of different materials, but is preferably made of a high-heat resistant plastic. In this way, the coldplate 20 may have a relatively light weight, especially when compared with other heat removing devices such as heat sinks, fan blowers, and/or traditional liquid cooling blocks. The cooling fluid may be a liquid, a gas, or a phase-changing fluid such as a refrigerant. The cooling fluid may be water, an antifreeze agent, such as ethylene glycol, or a solution thereof.

The first baseplate 22 includes a plurality of mounting holes 43 extending therethrough for securing the baseplate 22 together with the housing 40. The mounting holes 43 may be formed with countersinking to receive screws or other fasteners that are flush with the first surface 24 when installed.

A first jet-array plate 44 is disposed in the cooling passage 42 and extends parallel to and spaced apart from the first baseplate 22 to subdivide the cooling passage 42 into a supply header 46 opposite the first baseplate 22 and a first main channel 48 extending between the first jet-array plate 44 and the first baseplate 22. The first jet-array plate 44 defines a plurality of first orifices 50 extending therethrough to convey the cooling fluid from the supply header 46 and into the first main channel 48, with the first orifices 50 being configured to direct the fluid toward predetermined zones 52 on the second surface 26 of the first baseplate 22. The first jet-array plate 44 may be made of Teflon, Delrin, Aluminum, or any other low-cost plastic type material.

In some embodiments, each of the first heat sources 10 is directly aligned with a corresponding one of the predetermined zones 52 on the second surface 26 of the first baseplate 22. The predetermined zones 52 are preferably located directly opposite the first heat sources 10, such that the cooling fluid is directed and accelerated by each of the first orifices 50 as a jet toward a corresponding one of the predetermined zones 52 for removing heat therefrom. In other words, the jets preferably provide the most cooling directly to the predetermined zones that are immediately across the first baseplate 22 from corresponding ones of the first heat sources 10. Additional first orifices 50 may be provided to direct jets toward any hot spots or where symmetrical cooling is required.

The jets of the cooling fluid may have a velocity that is substantially higher than the velocity of other fluid in the coldplate 20, 120. As shown in FIG. 1 for example, the cooling fluid directed as jets out of the first orifices 50 may have a velocity of 1.2 m/s or greater, whereas cooling fluid in the cooling passage 42 outside of the jets may have velocities of 0.48 m/s or less. Actual velocities of the cooling fluid may vary depending on a number of factors including, for example, cooling flow volume, type of the cooling fluid, and cooling requirements of the heat sources 10, 110.

As shown in FIG. 1, the housing 40 defines a fluid inlet 54 in fluid communication with the supply header 46 for receiving the cooling fluid. The housing 40 also defines a fluid outlet 56 in fluid communication with the first main channel 48 for conveying the cooling fluid out of the first main channel 48.

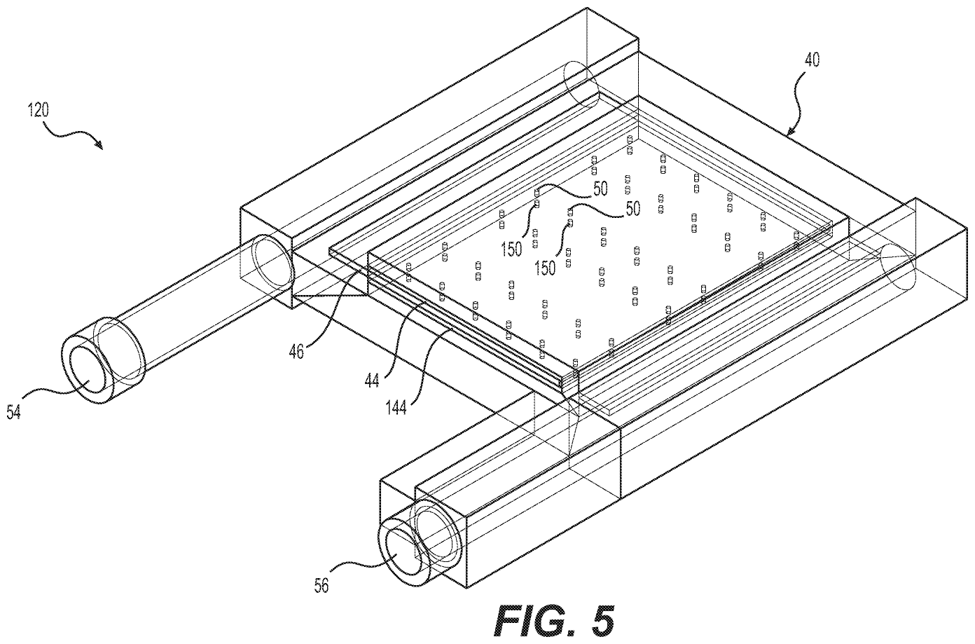

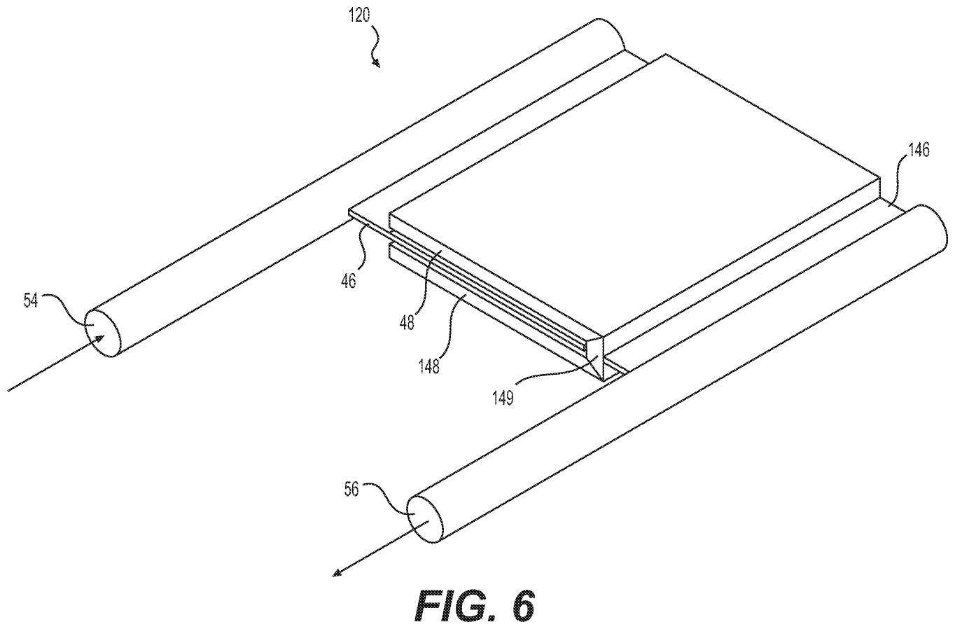

In some embodiments, and as shown in FIGS. 5-8, the coldplate 20, 120 may be configured as a double-layer coldplate 120 including a second baseplate 122 which may be similar or identical to the first baseplate 22. Such a double-layer coldplate 120 may be sandwiched between two power converters of equal or unequal power ratings and designs.

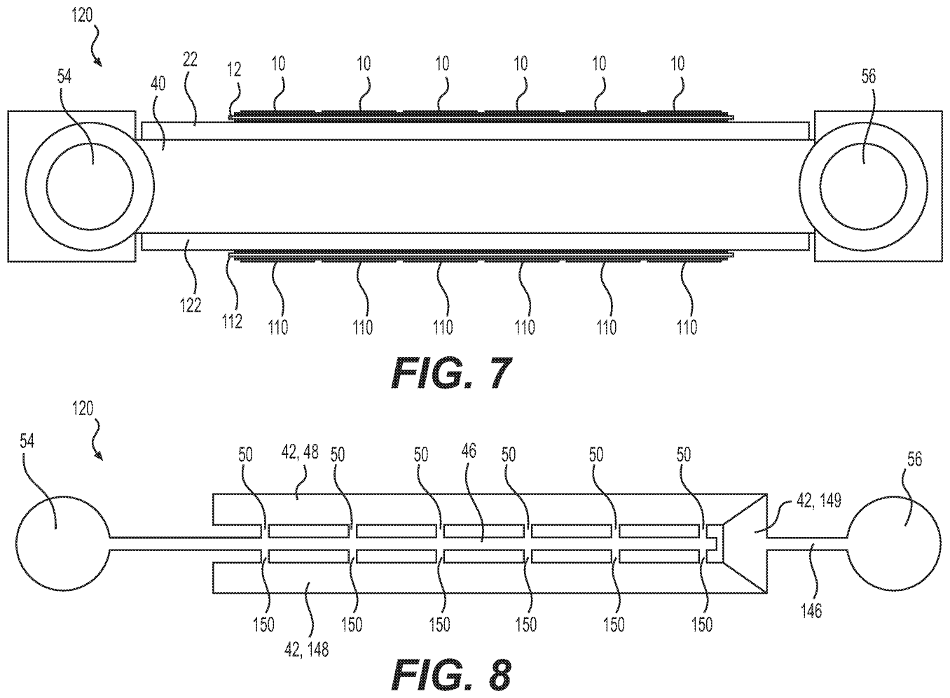

The second baseplate 122 includes a first surface 124 in thermally-conductive communication with each of a plurality of second heat sources 110, as shown in FIG. 5. The second heat sources 110 may be in direct physical contact with the second baseplate 122 as shown in FIG. 7. Alternatively, a thermally-conductive device and/or substance may extend therebetween. For example, thermally-conductive paste may be used to enhance thermal conduction between the second heat sources 110 and the second baseplate 122. Other devices, such as a heat pipe, may transfer heat between the second heat sources 110 and the second baseplate 122, allowing the first heat sources 10 to be physically spaced apart from the second baseplate 122. The second heat sources 110 may be semiconductor switches, such as Si, SiC, and/or GaN-based devices. The second heat sources 110 may also be other devices such as, for example, capacitors, inductors, and/or transformers. The second baseplate 122 includes a second surface 126 opposite the first surface 124 and configured to transfer heat from the second heat sources 110 through the first baseplate 22 and into a fluid in contact with the second surface 126. In other words, the second baseplate 122 is preferably formed as a relatively thin sheet that is thick enough to maintain structural rigidity, but thin enough to efficiently conduct heat directly therethrough between the first surface 124 and the second surface 126. In some embodiments, the second baseplate 122 may be embedded with one or more phase change materials (PCM) to enhance heat transfer. In some embodiments, and as shown in FIGS. 5-8, the second baseplate 122 extends parallel to and spaced apart from the first baseplate 22, with the supply header 46 disposed therebetween. Alternatively, the baseplates 22, 122, may have another configuration. For example, the baseplates 22, 122 may be oriented at a right angle or an oblique angle to one another.

A second jet-array plate 144 is disposed in the cooling passage 42 and extends parallel to and spaced apart from the second baseplate 122 to separate the supply header 46 from a second main channel 148 which extends between the second jet-array plate 144 and the second baseplate 122. The second jet-array plate 144 may be similar or identical to the first jet-array plate 44. The second jet-array plate 144 defines a plurality of second orifices 150, with each of the second orifices 150 extending through the second jet-array plate 144 to convey fluid from the supply header 46 and into the second main channel 148. The second orifices 150 are configured to direct the fluid toward predetermined zones on the second surface 26 of the second baseplate 122. As shown in FIG. 8, the first main channel 48 and the second main channel 148 may be joined at a convergence region 149 which is in fluid communication with the fluid outlet 56 via a return header 146, thus providing for cooling fluid to flow from either or both of the main channels 48, 148 to the fluid outlet 56.

In some embodiments, the second baseplate 122 extends in a generally flat plane, and a central region of the second baseplate 122 defines a plurality of fins 32 extending transverse to the generally flat plane of the second baseplate 122 and into the cooling passage 42. Fins 32 may be formed in the second baseplate 122 by any suitable process. For example, the fins 32 may be machined into the second baseplate 122. Alternatively or additionally, the fins 32 may be formed together with the second baseplate 122, for example, by casting. Alternatively or additionally, the fins 32 may be formed in the second baseplate 122 by compressive force, such as by stamping or rolling. Alternatively or additionally, the fins 32 may be formed in the second baseplate 122 by a 3D printing process, such as additive manufacturing (AM). Design details, such as fins 32 or ribs 32, may be applied identically or differently for each of the baseplates 22, 122. For example, neither, either, or both of the baseplates 22, 122 may have fins 32 or ribs 32, and those fins 32 or ribs 32 may be similar or different between the baseplates 22, 122.

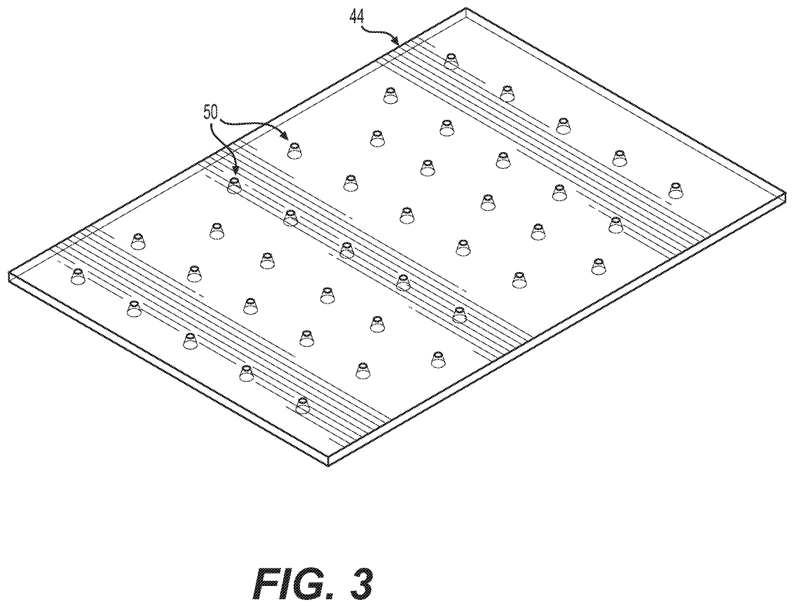

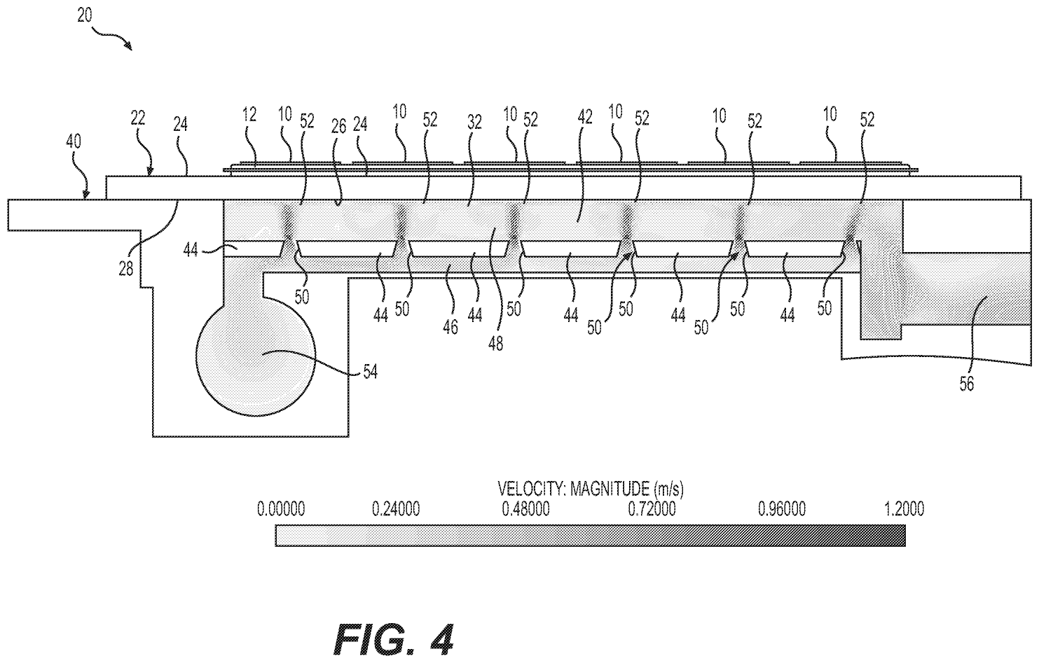

The orifices 50, 150 may be formed with a specific shape and/or direction to function as nozzles and to direct the flow of the cooling fluid as necessary. The orifices 50, 150 may have diameters that are optimized to provide a low pressure drop at a given coolant flow rate and temperature, while providing a uniform cooling. Some or all of the orifices 50, 150 may be cylindrical drilled holes that extend generally perpendicularly to the plane of the first jet-array plate 44. Alternatively or additionally, some or all of the orifices 50, 150 may include a frustoconical section, such as a chamfered shape shown in FIGS. 3 and 4. This chamfered shape reduces the pressure drop and avoids flow separation in the orifices 50, 150. In some embodiments, some or all of the orifices 50, 150 may include a cylindrical bore as well as a frustoconical section, such as a chamfered shape shown in FIGS. 3 and 4. The orifices 50, 150 may have other shapes, such as slots or wedges, to direct the flow of the cooling fluid as necessary. Any or all of the baseplates 22, 122 may include orifices 50, 150 having two or more different sizes and/or two or more different shapes.

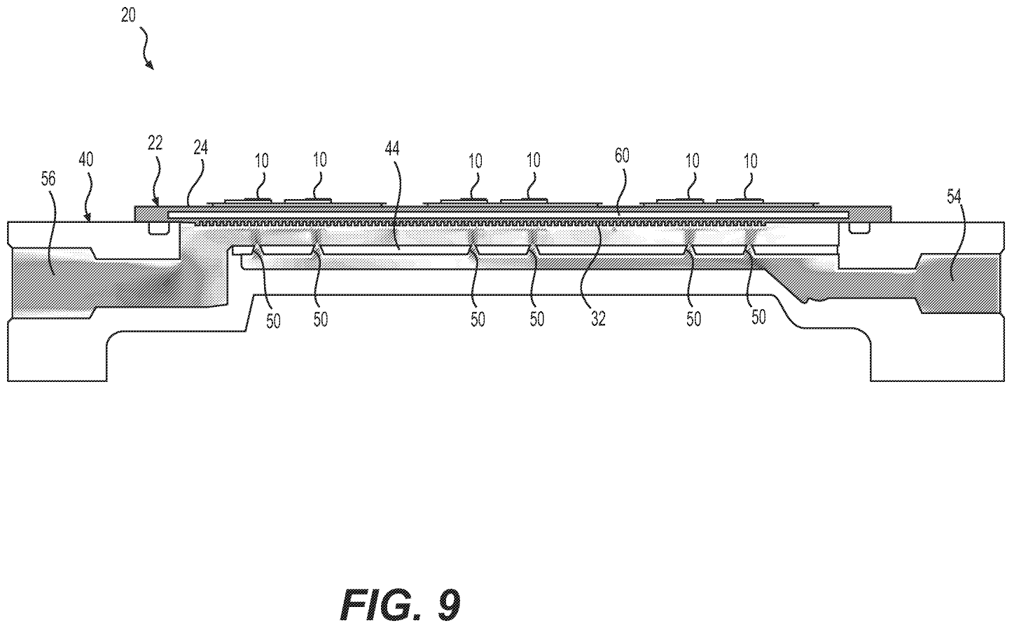

In some embodiments, and as shown in FIG. 9, one or more of the baseplates 22, 122 defines one or more chambers 60 containing phase change material (PCM) to enhance heat transfer through corresponding ones of the baseplates 22, 122.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A coldplate comprising:
a baseplate of thermally-conductive material including a first surface and a second surface opposite said first surface, with said first surface configured to be in thermally-conductive communication with a plurality of heat sources;
a housing and said baseplate together defining a cooling passage for circulation of a cooling fluid to remove heat from said baseplate;
a jet-array plate disposed in said cooling passage and extending parallel to and spaced apart from said baseplate to subdivide said cooling passage into a supply header opposite said baseplate and a main channel extending between said jet-array plate and said baseplate;
said jet-array plate defining a plurality of orifices extending therethrough to convey fluid from said supply header and into said main channel, with said orifices being configured to direct the fluid toward predetermined zones on said second surface of said baseplate.

2. The coldplate of claim 1, wherein each of the heat sources is directly aligned with a corresponding one of the predetermined zones on said second surface of said baseplate.

3. The coldplate of claim 1, wherein said baseplate extends in a generally flat plane, and wherein a central region of said baseplate defines a plurality of fins extending transverse to the generally flat plane of said baseplate and into said cooling passage.

4. The coldplate of claim 3, wherein said fins of said plurality of fins extend parallel to one another.

5. The coldplate of claim 3, wherein said fins of said plurality of fins have a generally rectangular cross-section.

6. The coldplate of claim 3, wherein said fins of said plurality of fins are formed in said baseplate by machining or by compressive force.

7. The coldplate of claim 3, wherein said fins of said plurality of fins are formed in said baseplate by casting.

8. The coldplate of claim 3, wherein said fins of said plurality of fins are formed in said baseplate by 3D printing.

9. The coldplate of claim 1, wherein at least some of said plurality of orifices are generally cylindrical.

10. The coldplate of claim 1, wherein at least some of said plurality of orifices include a frustoconical section.

11. The coldplate of claim 1, further comprising:
a second baseplate of thermally-conductive material including a first surface and a second surface opposite said first surface, with said first surface configured to be in thermally-conductive communication with a second plurality of heat sources;
a second jet-array plate disposed in said cooling passage and extending parallel to and spaced apart from said second baseplate to separate said supply header from a second main channel extending between said second jet-array plate and said second baseplate;
said second jet-array plate defining a plurality of second orifices extending therethrough to convey fluid from said supply header and into said second main channel, with said second orifices being configured to direct the fluid toward predetermined zones on said second surface of said second baseplate.

12. The coldplate of claim 11, wherein said second baseplate extends parallel to and spaced apart from said baseplate, with said supply header disposed therebetween.

13. The coldplate of claim 11, wherein said second baseplate extends in a generally flat plane, and wherein a central region of said second baseplate defines a plurality of fins extending transverse to the generally flat plane of said second baseplate and into said cooling passage.

14. An enclosure for an electronic device including the coldplate of claim 1.

15. The enclosure of claim 14, wherein the electronic device comprises a printed circuit board disposed parallel to said first surface of said baseplate.

16. The coldplate of claim 1, wherein said jet array plate is spaced apart from said baseplate, with no portion of said jet array plate extending above a lowest surface of said baseplate.

17. A coldplate comprising:
a baseplate of thermally-conductive material including a first surface and a second surface opposite said first surface, with said first surface configured to be in thermally-conductive communication with a plurality of heat sources;
a housing and said baseplate together defining a cooling passage for circulation of a cooling fluid to remove heat from said baseplate;
a jet-array plate disposed in said cooling passage and extending parallel to and spaced apart from said baseplate to subdivide said cooling passage into a supply header opposite said baseplate and a main channel extending between said jet-array plate and said baseplate;
said jet-array plate defining a plurality of orifices extending therethrough to convey fluid from said supply header and into said main channel, with said orifices being configured to direct the fluid toward predetermined zones on said second surface of said baseplate;
wherein said baseplate extends in a generally flat plane, and wherein a central region of said baseplate defines a plurality of fins extending transverse to the generally flat plane of said baseplate and into said cooling passage; and
wherein said fins of said plurality of fins are formed in said baseplate by machining or by compressive force.

18. A coldplate comprising:
a baseplate of thermally-conductive material including a first surface and a second surface opposite said first surface, with said first surface configured to be in thermally-conductive communication with a plurality of heat sources;
a housing and said baseplate together defining a cooling passage for circulation of a cooling fluid to remove heat from said baseplate;
a jet-array plate disposed in said cooling passage and extending parallel to and spaced apart from said baseplate to subdivide said cooling passage into a supply header opposite said baseplate and a main channel extending between said jet-array plate and said baseplate;
said jet-array plate defining a plurality of orifices extending therethrough to convey fluid from said supply header and into said main channel, with said orifices being configured to direct the fluid toward predetermined zones on said second surface of said baseplate;
a second baseplate of thermally-conductive material including a first surface and a second surface opposite said first surface, with said first surface configured to be in thermally-conductive communication with a second plurality of heat sources;
a second jet-array plate disposed in said cooling passage and extending parallel to and spaced apart from said second baseplate to separate said supply header from a second main channel extending between said second jet-array plate and said second baseplate;
said second jet-array plate defining a plurality of second orifices extending therethrough to convey fluid from said supply header and into said second main channel, with said second orifices being configured to direct the fluid toward predetermined zones on said second surface of said second baseplate

19. The coldplate of claim 18, wherein said second baseplate extends parallel to and spaced apart from said baseplate, with said supply header disposed therebetween.

20. The coldplate of claim 18, wherein said second baseplate extends in a generally flat plane, and wherein a central region of said second baseplate defines a plurality of fins extending transverse to the generally flat plane of said second baseplate and into said cooling passage.
